(19) United States
(12) Patent Application Publication
(10) Pub. No.: US 2025/0157545 A1
(43) Pub. Date: May 15, 2025

(54) POWER SUPPLYING CIRCUIT AND ASSOCIATED SWITCH CONTROLLER FOR NON-VOLATILE MEMORY

(71) Applicant: eMemory Technology Inc., Hsin-Chu (TW)

(72) Inventor: Wei-Chiang Ong, Hsinchu County (TW)

(21) Appl. No.: 18/892,600

(22) Filed: Sep. 23, 2024

Related U.S. Application Data
(60) Provisional application No. 63/598,558, filed on Nov. 14, 2023.

(51) Int. Cl. G11C 16/16; G11C 16/30

(52) U.S. Cl. CPC G11C 16/16; G11C 16/30

(57) ABSTRACT

A power supplying circuit and an associated switch controller for a non-volatile memory are provided. When the sector erase is performed, the voltage stress withstood by the switching transistors in the power supplying circuit is lower than the maximum voltage stress. In addition, the voltage stress withstood by all transistors in the switch controller is lower than the maximum voltage stress. In other words, when the sector erase is performed, all switch controllers and all switching transistors in the power supplying circuit can be operated normally. In addition, an erase voltage is provided to a specified sector of the array structure, so that all memory cells in the specified sector are erased into the erase state.

This application claims the benefit of U.S. provisional application Ser. No. 63/598,558, filed Nov. 14, 2023, the subject matters of which is incorporated herein by reference.

### FIELD OF THE INVENTION

The present invention relates to a circuit of a non-volatile memory, and more particularly to a power supplying circuit and an associated switch controller for a non-volatile memory.

### BACKGROUND OF THE INVENTION

FIG. 1A is a schematic circuit diagram illustrating a circuitry structure of a conventional non-volatile memory cell 10. Hereinafter, the non-volatile memory cell is also referred to as a memory cell. The memory cell 10 comprises a select transistor M_{S}, a floating gate transistor M_{F} and a capacitor C. Since the memory cell 10 comprises two transistors and one capacitor, the memory cell 10 is referred as a 2T1C cell. The source terminal of the select transistor M_{S} is connected with a source line SL. The gate terminal of the select transistor M_{S} is connected with a word line WL. The source terminal of the floating gate transistor M_{F} is connected with the drain terminal of the select transistor M_{S}. The drain terminal of the floating gate transistor M_{F} is connected with a bit line BL. A first terminal of the capacitor C is connected with a floating gate 12 of the floating gate transistor M_{F}. A second terminal of the capacitor C is connected with an erase line EL.

By providing appropriate bias voltages to the source line SL, the word line WL, the bit line BL and the erase line EL, a program action, an erase action or a read action is selectively performed on the memory cell 10. For example, when the erase action is performed on the memory cell 10, the source line SL, the word line WL, and the bit line BL receive a ground voltage (0V), and the erase line EL receives an erase voltage V_{EE}. Consequently, the electrons stored in the floating gate transistor M_{F} will be ejected from the floating gate 12 to the erase line EL through the capacitor C. Under this circumstance, the memory cell is in an erase state.

When a program voltage V_{PP} is provided to the memory cell 10, the program action is performed on the memory cell 10. When a read voltage V_{RD} is provided to the memory cell 10, the read action is performed on the memory cell. Generally, the erase voltage V_{EE} is higher than the program voltage V_{PP}, and the program voltage V_{PP} is higher than the read voltage V_{RD}. For example, the erase voltage V_{EE} is 16V, the program voltage V_{PP} is 7V, and the read voltage V_{RD} is 1.2V.

The circuitry structure of the memory cell 10 is not restricted to the circuitry structure shown in FIG. 1A. That is, the program action, the erase action or the read action is selectively performed on the memory cell with another circuitry structure.

FIG. 1B is a schematic circuit diagram illustrating the architecture of a non-volatile memory 100. The non-volatile memory 100 comprises an array structure 110, a word line driver 120, a bit line driver 130, a sensing circuit 140, a processing unit 150 and a power supplying circuit 160.

The array structure 110 comprises M×N memory cells. The structures of these memory cells are identical to the structure of the memory cell 10 shown in FIG. 1A. The M×N memory cells are connected with the source line SL. The N memory cells in the first row of the array structure 110 are connected with the word line WL₁. The N memory cells in the first row are respectively connected with the corresponding N bit lines BL₁˜BL_{N}. The N memory cells in the second row of the array structure 110 are connected with the word line WL₂. The N memory cells in the second row are respectively connected with the corresponding N bit lines BL₁˜BL_{N}. The rest may be deduced by analogy. The M memory cells in the M-th row of the array structure 110 are connected with the word line WL_{M}. The N memory cells in the M-th row are respectively connected with the corresponding N bit lines BL₁˜BL_{N}.

The array structure 110 is further divided into X sectors. The memory cells in the X sectors are connected with the corresponding erase lines EL₁˜EL_{X}, respectively. For example, each sector contains two rows of memory cells (i.e., 2×N memory cells), and X=M/2. That is, in the array structure 110, the first sector SE₁ contains the N memory cells in the first row and the N memory cells in the second row (i.e., 2×N memory cells), and the 2×N memory cells in the first sector SE₁ are connected with the erase line EL₁. Similarly, the second sector SE₂ contains the N memory cells in the third row and the N memory cells in the fourth row (i.e., 2×N memory cells), and the 2×N memory cells in the second sector SE₂ are connected with the erase line EL₂. The rest may be deduced by analogy. Similarly, the X-th sector SE_{X} contains the N memory cells in the (M−1)-th row and the N memory cells in the M-th row (i.e., 2×N memory cells), and the 2×N memory cells in the X-th sector SE_{X} are connected with the erase line EL_{X}.

The processing unit 150 is connected with a host (not shown). The processing unit 150 receives from the host a command CMD instructing the non-volatile memory 100 to perform the read, program or erase action. According to the command CMD, the processing unit 150 generates a driving signal D_{RV} and a control signal set Ctrl.

The word line driver 120 and the bit line driver 130 receive the driving signal D_{RV}. The word line driver 120 is connected with the word lines WL₁˜WL_{M}. The bit line driver 130 is connected with the bit lines BL₁˜BL_{N}. According to the driving signal D_{RV}, the word line driver 120 and the bit line driver 130 activate the corresponding word line and the corresponding bit line. The sensing circuit 140 is connected with the bit line driver 130. When the read action is performed on a specified memory cell in the memory cell array 110, the sensing circuit 140 outputs a read data Da.

The power supplying circuit 160 receives the control signal set Ctrl and generates appropriate voltages to the source line SL and the erase lines EL₁˜EL_{X} according to the control signal set Ctrl. For example, when the program action is performed, the power supplying circuit 160 provides the program voltage V_{PP}. When the read action is performed, the power supplying circuit 160 provides the read voltage V_{RD}. When the erase action is performed, the power supplying circuit 160 provides the erase voltage V_{EE}. Generally, the erase voltage V_{EE} is the maximum voltage inside the non-volatile memory 100.

For example, the processing unit 150 receives the command CMD from the host to erase all of the memory cells in the first sector SE₁. The command CMD contains an address signal to indicate a specified sector in the array structure 110. In addition, this action is referred as a sector erase.

That is, the processing unit 150 generates the control signal set Ctrl to the power supplying circuit 160 according to the received command CMD. Consequently, the power supplying circuit 160 provides the erase voltage V_{EE} to the erase line EL₁, and the power supplying circuit 160 does not provide the erase voltage V_{EE} to other erase lines EL₂˜EL_{X}. Of course, the power supplying circuit 160 also provides the ground voltage (0V) to the source line SL. In addition, the processing unit 150 generates the driving signal D_{RV} to the word line driver 120 and the bit line driver 130. Consequently, the word line driver 120 provides the ground voltage (0V) to the word lines WL₁˜WL_{M}, and the bit line driver 130 provides the ground voltage (0V) to the bit lines BL₁˜BL_{N}. Since the power supplying circuit 160 provides the erase voltage V_{EE} to the erase line EL₁, all of the memory cells in the first sector SE₁ are erased to the erase state when the erase voltage V_{EE} is received. Consequently, the sector erase is completed. Moreover, since the power supplying circuit 160 does not provide the erase voltage V_{EE} to other erase lines EL₂˜EL_{X}, the other sectors SE₂˜SE_{X} are not subjected to the sector erase.

FIG. 1C is a schematic circuit diagram of the power supplying circuit 160 in the non-volatile memory 100 shown in FIG. 1B. For example, the power supplying circuit 160 provides the erase voltage V_{EE}. As shown in FIG. 1C, the power supplying circuit 160 comprises a voltage source 162 and a switching circuit 166. The switching circuit 166 is connected with the voltage source 162 and the erase lines EL₁˜EL_{X}. In addition, the voltage source 162 generates the erase voltage V_{EE}. The control signal set Ctrl contains X control signals Ctrl₁˜Ctrl_{X}.

The switching circuit 166 comprises X power paths 171˜17X. These power paths 171˜17X are controlled according to the X control signals Ctrl₁˜Ctrl_{X}. The X power paths 171˜17X comprise respective power switches. The power switches are P-type switching transistors M_{SW1}˜M_{SWX}. The first terminals of the X switching transistors M_{SW1}˜M_{SWX} are connected with the output terminal of the voltage source 162. The second terminals of the X switching transistors M_{SW1}˜M_{SWX} are coupled to the corresponding erase lines EL₁˜EL_{X}, respectively. The control terminals of the switching transistors M_{SW1}˜M_{SWX} receive the corresponding control signals Ctrl₁˜Ctrl_{X}, respectively. In other words, the plural power paths 171˜17X are constituted by the X switching transistors M_{SW1}˜M_{SWX}, respectively. In addition, the on/off states of the power path 171˜17X are controlled according to the control signal set Ctrl. In case that one of the power paths 171˜17X is turned on, the erase voltage V_{EE} is transmitted to the corresponding erase line. Of course, in some cases, the power switches are N-type switching transistors.

In addition to the power paths 171˜17X, the switching circuit 166 may be equipped with other power paths (not shown) for transmitting the program voltage V_{PP} and the read voltage V_{RD}. When the program action, the read action or the erase action is performed, appropriate voltages (e.g., the program voltage V_{PP}, the read voltage V_{RD} or the erase voltage V_{EE}) can be provided to the source line SL and the erase lines EL₁˜EL_{X}.

For example, when the first sector SE₁ in the array structure 110 of the non-volatile memory 100 is subjected to the sector erase, the processing unit 150 will activate the control signal Ctrl₁ in the control signal set Ctrl but not activate other control signals Ctrl₂˜Ctrl_{X}. Under this circumstance, the switching transistor M_{SW1} is turned on, and the power path 171 is turned on.

Consequently, the erase voltage V_{EE} is transmitted to the erase line EL₁ through the power path 171. The other switching transistors M_{SW2}˜M_{SWX} are turned off, and the power paths 172˜17X are turned off. Consequently, the erase voltage V_{EE} cannot be transmitted to the erase lines EL₂˜EL_{X}. Meanwhile, in the non-volatile memory 100, all memory cells in the first sector SE₁ are erased into the erase state, but the memory cells in the other sectors SE₂˜SE_{X} are not erased into the erase state.

Generally, the signals in the control signal set Ctrl from the processing unit 150 are logic signals. The logic high level of each logic signal is equal to a logic supply voltage V_{DD}. The logic low level of each logic signal is equal to the ground voltage (0V). For example, the logic supply voltage V_{DD} is approximately in the range between 1.2 V and 3.3 V. In addition, the maximum voltage stress that the switching transistors M_{SW1}˜M_{SWX} can withstand is about 8.5 V.

As mentioned above, the erase voltage V_{EE} is 16 V. When the control signal Ctrl₁ is activated, the control signal Ctrl₁ is in the logic low level state (0V), and the voltage stress between the source terminal and the gate terminal of the switching transistor M_{SW1} is 16 V. This voltage stress will damage the switching transistor M_{SW1}. Similarly, when the control signal Ctrl₂ is not activated, the control signal Ctrl₂ is in the logic high level state (e.g., 3.3V), and the voltage stress between the source terminal and the gate terminal of the switching transistor M_{SW2} is 12.7 V. This voltage stress will also damage the switching transistor M_{SW2}.

### SUMMARY OF THE INVENTION

An embodiment of the present invention provides a power supplying circuit for a non-volatile memory. The power supplying circuit includes a voltage source and a switching circuit. The voltage source outputs a high voltage, a low voltage and a decoupling signal. The switching circuit includes a power switch and a switch controller. A first terminal of the power switch receives the high voltage. A second terminal of the power switch is coupled to an erase line of the non-volatile memory. The switch controller includes a latch, a first driving stage, a first control stage and a second control stage. A first power terminal of the latch receives the high voltage. A second power terminal of the latch receives the low voltage. A first control terminal of the latch is connected with a first node. A second control terminal of the latch is connected with a second node. A first power terminal of the first driving stage receives the high voltage. A second power terminal of the first driving stage receives the low voltage. An input terminal of the first driving stage is connected with the first node. An output terminal of the first driving stage generates a switching signal to a control terminal of the power switch. In addition, the on/off states of the power switch are controlled according to the switching signal. The first control stage is connected with the first node. The first control stage receives a control signal and the decoupling signal. The second control stage is connected with the second node. The second control stage receives an inverted control signal and the decoupling signal. In a logic phase of a sector erase, the high voltage is equal to a logic supply voltage, the low voltage is equal to a ground voltage and the control signal is stored in the latch. In a transition phase of the sector erase, the high voltage rises from the logic supply voltage to a first voltage, the low voltage is equal to the ground voltage. In an erase phase of the sector erase, the high voltage rises from the first voltage to an erase voltage, the low voltage rises from the ground voltage to a second voltage, the erase voltage is higher than the second voltage, and the latch and the first driving stage generates the switching signal according to the high voltage and the low voltage. The decoupling signal is in a range of the high voltage and the low voltage during the logic phase, the transition phase and the erase phase.

Another embodiment of the present invention provides a power supplying circuit for a non-volatile memory. The power supplying circuit includes a power switch, a switch controller and a voltage source. The voltage source outputs a high voltage, a low voltage and a decoupling signal. A first terminal of the power switch receives the high voltage. A second terminal of the power switch is coupled to an erase line of the non-volatile memory. The switch controller receives the high voltage, the low voltage and the decoupling signal. The switch controller includes a latch, a first driving stage, a first control stage and a second control stage. A first control terminal of the latch is coupled to a first node. A second control terminal of the latch is coupled to a second node. The first driving stage is coupled to the first node and a control terminal of the power switch, and outputs the high voltage or the low voltage as a switching signal to the control terminal of the power switch according to a voltage at the first node. The first control stage is coupled to the first node, and controls the voltage at the first node according to a control signal and the decoupling signal. The second control stage is coupled to the second node, and controls a voltage at the second node according to an inverted control signal and the decoupling signal. The high voltage, the low voltage and the decoupling signal are increased in a multi-step manner during a sector erase of the non-volatile memory. The decoupling signal is in a range of the high voltage and the low voltage during the sector erase.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram illustrating a circuitry structure of a conventional non-volatile memory cell;

FIG. 1B (prior art) is a schematic circuit diagram illustrating the architecture of a non-volatile memory;

FIG. 1C (prior art) is a schematic circuit diagram of the power supplying circuit in the non-volatile memory shown in FIG. 1B;

FIG. 2A is a schematic circuit diagram illustrating a power supplying circuit according to an embodiment of the present invention;

FIG. 2B is a table about the relationship between different supply voltages and different phases for the power supplying circuit shown in FIG. 2A;

FIG. 3 is a schematic circuit diagram illustrating a switch controller according to a first embodiment of the present invention;

FIG. 4 is a schematic circuit diagram illustrating a switch controller according to a second embodiment of the present invention;

FIG. 5 is a schematic circuit diagram illustrating a switch controller according to a third embodiment of the present invention;

FIGS. 6A, 6B and 6C schematically illustrate the voltages at various nodes of the switch controller of the third embodiment in different phases;

FIG. 7 is a schematic circuit diagram illustrating a switch controller according to a fourth embodiment of the present invention;

FIGS. 8A, 8B and 8C schematically illustrate the voltages at various nodes of the switch controller of the fourth embodiment in different phases;

FIG. 9 is a schematic circuit diagram illustrating a switch controller according to a fifth embodiment of the present invention; and

FIG. 10 is a schematic circuit diagram illustrating the voltage source in the power supplying circuit.

### DETAILED DESCRIPTION OF PREFERRED EMBODIMENTS

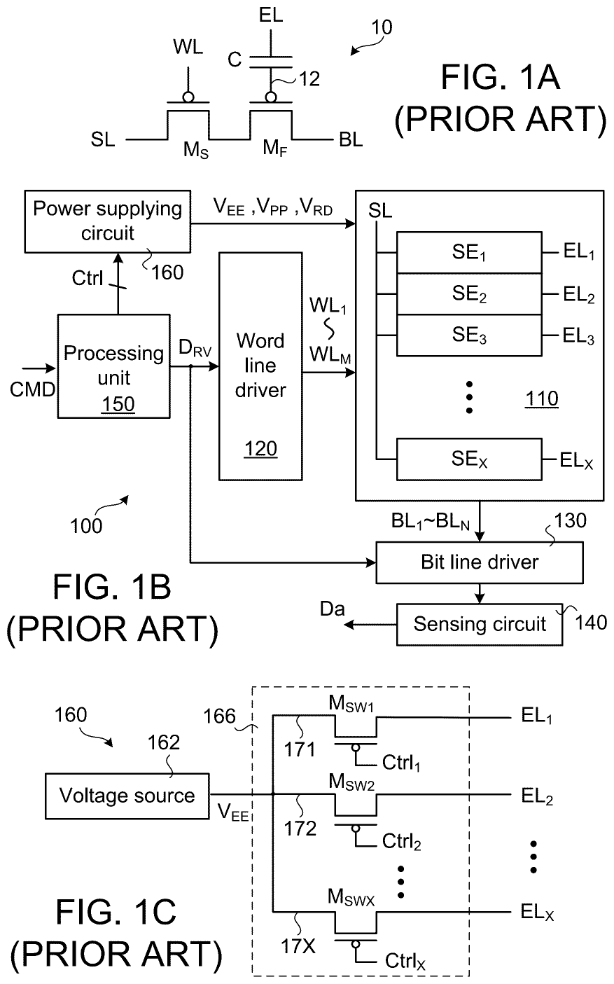

The present invention provides a power supplying circuit and an associated switch controller for a non-volatile memory. The power supplying circuit of the present invention can be used to replace the power supplying circuit 160 shown in FIG. 1B. The power supplying circuit comprises plural switch controllers for controlling the power switches. Consequently, all power switches can be operated normally within the safe operating area (SOA). Since the switch controller also receives the high voltage, the present invention provides a multi-step power-up control method to control the switch controller. Consequently, the electronic components in the switch controller can also be operated normally within the SOA.

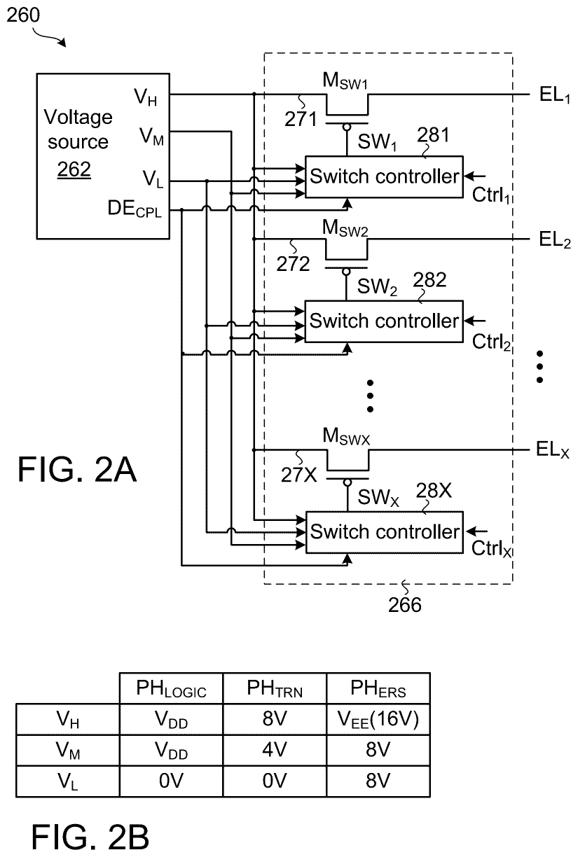

FIG. 2A is a schematic circuit diagram illustrating a power supplying circuit 260 according to an embodiment of the present invention. FIG. 2B is a table about the relationship between different supply voltages and different phases for the power supplying circuit 260 shown in FIG. 2A. The power supplying circuit 260 can be applied to the non-volatile memory 100 of FIG. 1B, as an alternative of the power supplying circuit 160. For illustration, in the following embodiment, the supply voltage provided by the power supplying circuit 260 is the erase voltage V_{EE}.

The power supplying circuit 260 comprises a voltage source 262 and a switching circuit 266. The switching circuit 266 is connected with the voltage source 262 to receive a high voltage V_{H}, a medium voltage V_{M} and a low voltage V_{L} from the voltage source 262. In addition, the voltage source 262 further generates a decoupling signal DE_{CPL} to the switching circuit 266.

When the power supplying circuit 260 is in different phases of a sector erase, the high voltage V_{H}, the medium voltage V_{M}, the low voltage V_{L} from the voltage source 262 will be subjected to changes. For example, in successive different phases of the sector erase, the high voltage V_{H}, the medium voltage V_{M}, the low voltage V_{L} will rise or remain unchanged only, but these voltages will not fall. Moreover, when the power supplying circuit 260 is in different phases of the sector erase, the voltage level of the decoupling signal DE_{CPL} will also change and will not fall. The high voltage V_{H} is higher than the low voltage V_{L}. The medium voltage V_{M} is lower than or equal to the high voltage V_{H}. The medium voltage V_{M} is higher than or equal to the low voltage V_{L}. That is, the medium voltage V_{M} is in the range of the high voltage V_{H} and the low voltage V_{L}. The voltage level of the decoupling signal DE_{CPL} is lower than or equal to the high voltage V_{H}. The voltage level of the decoupling signal DE_{CPL} is higher than or equal to the low voltage V_{L}. That is, the voltage level of the decoupling signal DE_{CPL} is in the range of the high voltage V_{H} and the low voltage V_{L}.

The switching circuit 266 comprises X power paths 271˜27X and X switch controllers 281˜28X. The X power supply paths 271˜27X and the X switch controllers 281˜28X have a one-to-one correspondence. That is, one power path is connected with a switch controller. Furthermore, X switch controllers 281˜28X respectively receive corresponding control signals Ctrl₁˜Ctrl_{X} and respectively generate switching signals SW₁˜SW_{X} to respectively control the corresponding power paths 271˜27X.

Please refer to FIG. 2A again. The X power paths 271˜27X comprise respective power switches. In an embodiment, these power switches are P-type switching transistors M_{SW1}˜M_{SWX}. The first terminals of the X switching transistors M_{SW1}˜M_{SWX} are connected with the output terminal of the voltage source 262 to receive the high voltage V_{H}. The second terminals of the X switching transistors M_{SW1}˜M_{SWX} are coupled to the corresponding erase lines EL₁˜EL_{X}, respectively. The control terminals of the switching transistors M_{SW1}˜M_{SWX} receive the corresponding switching signals SW₁˜SW_{X}, respectively. In other words, the plural power paths 271˜27X are constituted by the X switching transistors M_{SW1}˜M_{SWX}, respectively. In some other embodiments, the power switches are N-type switching transistors.

The structures of the switch controllers 281˜28X are identical. The switch controllers 281 to 28X are connected with the voltage source 262 to receive the high voltage V_{H}, the medium voltage V_{M}, the low voltage V_{L} and the decoupling signal DE_{CPL}. The switch controllers 281˜28X receive the corresponding control signals Ctrl₁˜Ctrl_{X}, respectively. The control signals Ctrl₁˜Ctrl_{X} are respectively converted into the corresponding switching signals SW₁˜SW_{X} by the switch controllers 281˜28X. The on/off states of the X switching transistors M_{SW1}˜M_{SWX} are respectively controlled according to the switching signals SW₁˜SW_{X}. That is, the X power paths 271˜27X are selectively turned on or turned off according to the switching signals SW₁˜SW_{X}. In case that one of the power switch paths is turned on, the erase voltage V_{EE} generated based on the high voltage V_{H} can be transmitted to the corresponding erase line through the on-state power switch. For example, the maximum voltage stress that the switching transistors M_{SW1}˜M_{SWX} can withstand is about 8.5V. The voltage levels of the switching signals SW₁˜SW_{X} allow the X switching transistors M_{SW1}˜M_{SWX} to be operated normally within the SOA.

In successive different phases of the power supplying circuit 260, the high voltage V_{H}, the medium voltage V_{M} and the low voltage V_{L} will rise or remain unchanged only, but these voltages will not fall. Similarly, the voltage levels of the switching signals SW₁˜SW_{X} from the switch controllers 281˜28X change with different phases. When the non-volatile memory 100 performs the sector erase, the power supplying circuit 260 will sequentially enter a logic phase PH_{LOGIC}, a transition phase PH_{TRN} and an erase phase PH_{ERS}. In the erase phase PH_{ERS}, the erase voltage V_{EE} generated based on the high voltage V_{H} is transmitted to the corresponding erase line, and all memory cells in the corresponding sector are erased into the erase state. The time period of the logic phase PH_{LOGIC} is about 2 μs. The time period of the transition phase PH_{TRN} is about 6 μs. That is, when the sector erase is performed, the power supplying circuit 260 passes through the logic phase PH_{LOGIC} and the transition phase PH_{TRN} at first. That is, after about 8 μs, the power supplying circuit 260 enters the erase phase PH_{ERS}. In the erase phase PH_{ERS}, the power supplying circuit 260 can output the erase voltage V_{EE} generated based on the high voltage V_{H} to the corresponding erase line.

Please refer to FIG. 2B. In the logic phase PH_{LOGIC}, the high voltage V_{H} outputted from the voltage source 262 is equal to the logic supply voltage V_{DD}, the medium voltage V_{M} is equal to the logic supply voltage V_{DD}, and the low voltage V_{L} is equal to the ground voltage (0 V), the logic supply voltage V_{DD} is the same with the logic high level, and the ground voltage (0 V) is the same with the logic low level.

Please refer to FIG. 2B again. After the logic phase PH_{LOGIC}, the power supplying circuit 260 enters the transition phase PH_{TRN}. In the transition phase PH_{TRN}, the high voltage V_{H} from the voltage source 262 rises to 8V, the medium voltage V_{M} rises to 4 V, and the low voltage V_{L} is maintained at the ground voltage (0 V). For example, the high voltage V_{H} rises to a half of the erase voltage (i.e., V_{EE}/2), and the medium voltage V_{M} rises to one-quarter of the erase voltage (i.e., V_{EE}/4).

Please refer to FIG. 2B again. After the transition phase PH_{TRN}, the power supplying circuit 260 enters the erase phase PH_{ERS}. In the erase phase PH_{ERS}, the high voltage V_{H} from the voltage source 262 rises to 16 V, the medium voltage V_{M} rises to 8 V, and the low voltage V_{L} rises to 8 V. For example, the high voltage V_{H} rises to the erase voltage V_{EE}, the medium voltage V_{M} rises to a half of the erase voltage i.e., (V_{EE}/2), and the low voltage V_{L} rises to a half of the erase voltage (i.e., V_{EE}/2).

Please refer to FIG. 2B again. It is noted that the high voltage V_{H}, the medium voltage V_{M} and the low voltage V_{L} in the table of FIG. 2B are presented herein for illustration. The magnitudes of the high voltage V_{H}, the medium voltage V_{M}, the low voltage V_{L} and the decoupling signal DE_{CPL} are not restricted as long as (1) the high voltage V_{H} is higher than the low voltage V_{L} in any phase and (2) the medium voltage V_{M} is in the range of the high voltage V_{H} and the low voltage V_{L} in any phase. In addition, the decoupling signal DE_{CPL} is in the range of the high voltage V_{H} and the low voltage V_{L} in any phase. The switch controllers 281˜28X generate the switching signals SW₁˜SW_{X} according to the high voltage V_{H}, the medium voltage V_{M}, the low voltage V_{L} and the decoupling signal DE_{CPL}. Given that the high voltage V_{H} and the switching signals SW₁˜SW_{X} are supplied to the switching transistors M_{SW1}˜M_{SWX}, the magnitudes of the high voltage V_{H}, the medium voltage V_{M}, the low voltage V_{L} and the decoupling signal DE_{CPL} may be modified according to the magnitude of the erase voltage V_{EE} and the maximum voltage stress that the switching transistors M_{SW1}˜M_{SWX} can withstand. That is to say, the high voltage V_{H}, the medium voltage V_{M}, the low voltage V_{L} and the decoupling signal DE_{CPL} are increased in a multi-step manner during the sector erase of the non-volatile memory 100. Moreover, the decoupling signal DE_{CPL} is in a range of the high voltage V_{H} and the low voltage V_{L} during the sector erase.

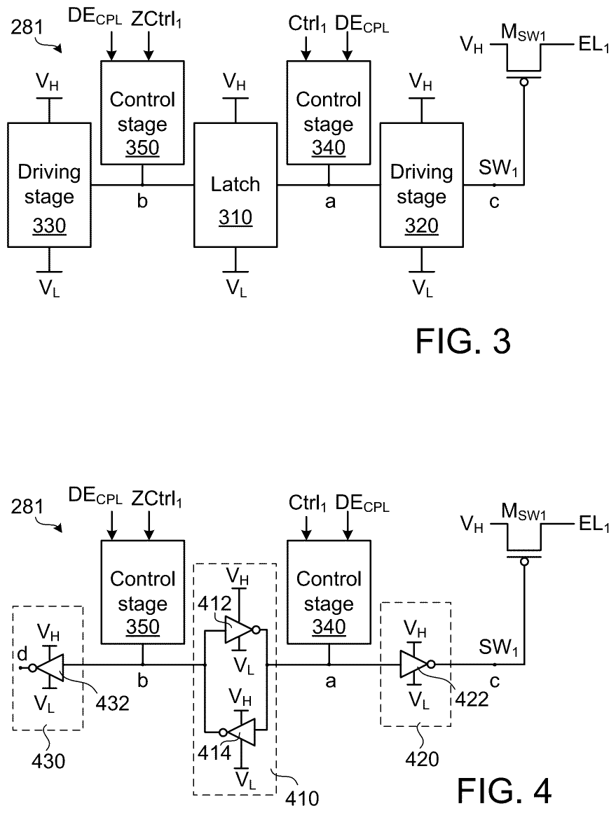

FIG. 3 is a schematic circuit diagram illustrating a switch controller 281 according to a first embodiment of the present invention. The structures of the switch controllers 281˜28X are identical. For succinctness, only the circuitry structure of the switch controller 281 will be described as follows. The circuitry structures of the other switch controllers 282˜28X will not be redundantly described herein. The switch controller 281 generates the switching signal SW₁. The control terminal of the switching transistor M_{SW1} receives the switching signal SW₁. The first terminal of the switching transistor M_{SW1} receives the high voltage V_{H}. The second terminal of the switching transistor M_{SW1} is coupled to the erase line EL₁.

In this embodiment, the switch controller 281 comprises a latch 310, two driving stages 320 and 330 and two control stages 340 and 350.

The two power terminals of the latch 310 receive the high voltage V_{H} and the low voltage V_{L}, respectively. The first control terminal of the latch 310 is couple to the node a. The second control terminal of the latch 310 is coupled to the node b.

The control stage 340 is connected with the node a. The control stage 340 receives the control signal Ctrl₁ and the decoupling signal DE_{CPL}. The control stage 350 is connected with the node b. The control stage 350 receives an inverted control signal ZCtrl₁ and the decoupling signal DE_{CPL}. That is to say, the control stage 340 is coupled to the node a, and the control stage 340 is configured to control the voltage at the node a according to the control signal Ctrl₁ and the decoupling signal DE_{CPL}. The control stage 350 is coupled to the node b, and the control stage 350 is configured to control the voltage at the node b according to the inverted control signal ZCtrl₁ and the decoupling signal DE_{CPL}.

The two power terminals of the driving stage 320 receive the high voltage V_{H} and the low voltage V_{L}, respectively. The input terminal of the driving stage 320 is connected with the node a. The output terminal of the driving stage 320 is connected with the control terminal of the switching transistor M_{SW1} through the node c. The output terminal of the driving stage 320 generates the switching signal SW₁. The two power terminals of the driving stage 330 receive the high voltage V_{H} and the low voltage V_{L}, respectively. The input terminal of the driving stage 330 is connected with the node b. The inverted control signal ZCtrl₁ is outputted from the processing unit 150 of the non-volatile memory 100. Alternatively, the switch controller 281 is equipped with an inverter (not shown). The inverter receives the control signal Ctrl₁ and outputs the inverted control signal ZCtrl₁. That is to say, the driving stage 320 is coupled to the node c and the control terminal of the switching transistor M_{SW1}, and the driving stage 320 is configured to output the high voltage V_{H} or the low voltage V_{L} as the switching signal SW₁ to the control terminal of the switching transistor M_{SW1} according to a voltage at the node a.

In the logic phase PH_{LOGIC}, the control signal Ctrl₁ is latched by the latch 310. That is, in the logic phase PH_{LOGIC}, the control signal Ctrl₁ is stored in the latch 310. In the transition phase PH_{TRN}, the decoupling signal DE_{CPL} is activated. The control stage 340 is decoupled from the node a, and the control stage 350 is decoupled from the node b. In the erase phase PH_{ERS}, the latch 310 and the driving stages 320 and 330 generate the switching signal SW₁ according to the high voltage V_{H} and the low voltage V_{L}. According to the switching signal SW₁, the switching transistor M_{SW1} is correspondingly controlled.

FIG. 4 is a schematic circuit diagram illustrating a switch controller 281 according to a second embodiment of the present invention. In this embodiment, the switch controller 281 comprises a latch 410, two driving stages 420 and 430 and two control stages 340 and 350. The structures of the control stages 340 and 350 are similar to those shown in FIG. 3, and are not redundantly described herein.

The latch 410 comprises two inverters 412 and 414. The two power terminals of the inverter 412 receive the high voltage V_{H} and the low voltage V_{L}, respectively. The two power terminals of the inverter 414 receive the high voltage V_{H} and the low voltage V_{L}, respectively. The input terminal of the inverter 412 is connected with the node b. The output terminal of the inverter 412 is connected with the node a. The input terminal of the inverter 414 is connected with the node a. The output terminal of the inverter 414 is connected with the node b.

The driving stage 420 comprises an inverter 422. The two power terminals of the inverter 422 receive the high voltage V_{H} and the low voltage V_{L}, respectively. The input terminal of the inverter 422 is connected with the node a. The output terminal of the inverter 422 is connected with the control terminal of the switching transistor M_{SW1} through the node c. The output terminal of the inverter 422 generates the switching signal SW₁. Similarly, the driving stage 430 comprises an inverter 432. The two power terminals of the inverter 432 receive the high voltage V_{H} and the low voltage V_{L}, respectively. The input terminal of the inverter 432 is connected with the node b. The output terminal of the inverter 432 is connected with the node d.

The operations of the switch controller 281 of this embodiment are similar to those of the switch controller 281 of the first embodiment and are not redundantly described herein. It is noted that the structure of the switch controller 281 may be modified according to the teachings of the present invention. For example, in another embodiment, the latch 410 comprises other types of electronic components. An example of the latch 410 is a D-latch or an SR-latch. Alternatively, the driving stage 420 comprises more inverters connected between the node a and the node c in series.

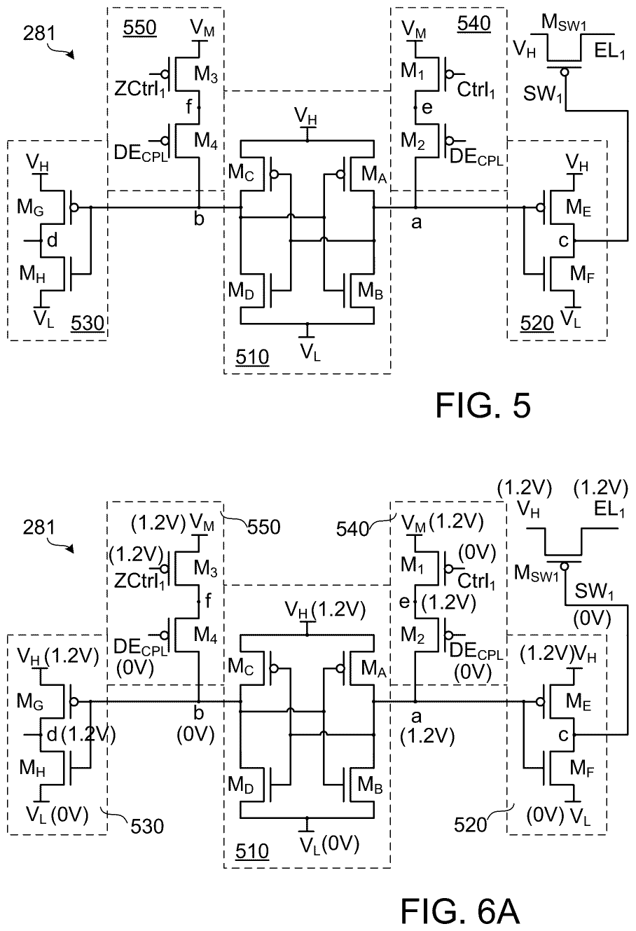

FIG. 5 is a schematic circuit diagram illustrating a switch controller 281 according to a third embodiment of the present invention. In this embodiment, the switch controller 281 comprises fewer transistors. Consequently, the layout area of the power supplying circuit 260 can be saved.

As shown in FIG. 5, the first control terminal of latch 510 is connected with the node a, and the second control terminal of latch 510 is connected with the node b. The transistor M_{A} and the transistor M_{B} are collaboratively formed as a first inverter. The input terminal of the first inverter is connected with the node b. The input terminal of the first inverter is connected with the gate terminal of the transistor M_{A} and the gate terminal of the transistor M_{B}. The output terminal of the first inverter is connected with the node a. The output terminal of the first inverter is connected with the drain terminal of the transistor M_{A} and the drain terminal of the transistor M_{B}. The source terminal of the transistor M_{A} receives the high voltage V_{H}. The source terminal of the transistor M_{B} receives the low voltage V_{L}. The transistor M_{C} and the transistor M_{D} are collaboratively formed as a second inverter. The input terminal of the second inverter is connected with the node a. In addition, the input terminal of the second inverter is connected with the gate terminal of the transistor M_{C} and the gate terminal of the transistor M_{D}. The output terminal of the second inverter is connected with the node b. The output terminal of the second inverter is connected with the drain terminal of the transistor M_{C} and the drain terminal of the transistor M_{D}. The source terminal of the transistor M_{C} receives the high voltage V_{H}. The source terminal of the transistor M_{D} receives the low voltage V_{L}.

The driving stage 520 comprises an inverter. The transistor M_{E} and the transistor M_{F} are collaboratively formed as the inverter. The input terminal of the inverter is connected with the node a. In addition, the input terminal of the inverter is connected with the gate terminal of the transistor M_{E} and the gate terminal of the transistor M_{F}. The source terminal of the transistor M_{E} receives the high voltage V_{H}. The source terminal of the transistor M_{F} receives the low voltage V_{L}. The output terminal of the inverter is connected with the node c. The output terminal of the inverter is connected with the drain terminal of the transistor M_{E} and the drain terminal of the transistor M_{F}. Furthermore, the voltage at the node c is the switching signal SW₁. The node c is connected with the gate terminal of the switching transistor M_{SW1}. Consequently, the switching transistor M_{SW1} receives the switching signal SW₁.

Similarly, the driving stage 530 comprises an inverter. The transistor M_{G} and the transistor M_{H} are collaboratively formed as the inverter. The input terminal of the inverter is connected with the node b. The input terminal of the inverter is connected with the gate terminal of the transistor M_{G} and the gate terminal of the transistor M_{H}. The source terminal of the transistor M_{G} receives the high voltage V_{H}. The source terminal of the transistor M_{H} receives the low voltage V_{L}. The output terminal of the inverter is connected with the node d. The output terminal of the inverter is connected with the drain terminal of the transistor M_{G} and the drain terminal of the transistor M_{H}. In fact, the driving stage 530 can be omitted to save the layout area of the power supplying circuit 260.

The control stage 540 comprises two transistors M₁ and M₂. The gate terminal of the transistor M₁ receives the control signal Ctrl₁. The source terminal of the transistor M₁ receives the medium voltage V_{M}. The drain terminal of the transistor M₁ is connected with the node e. The gate terminal of transistor M₂ receives the decoupling signal DE_{CPL}. The source terminal of the transistor M₂ is connected with the node e. The drain terminal of the transistor M₂ is connected with the node a.

The control stage 550 comprises two transistors M₃ and M₄. The gate terminal of the transistor M₃ receives the inverted control signal ZCtrl₁. The source terminal of the transistor M₃ receives the medium voltage V_{M}. The drain terminal of the transistor M₃ is connected with the node f. The gate terminal of transistor M₄ receives the decoupling signal DE_{CPL}. The source terminal of the transistor M₄ is connected with the node f. The drain terminal of the transistor M₄ is connected with the node b.

The control stages 540 and 550 are used to control the voltages at all nodes a˜f in the switch controller 281. Consequently, during the operations of the switch controller 281, all transistors M₁˜M₄ and M_{A}˜M_{H} can be operated normally within the SOA.

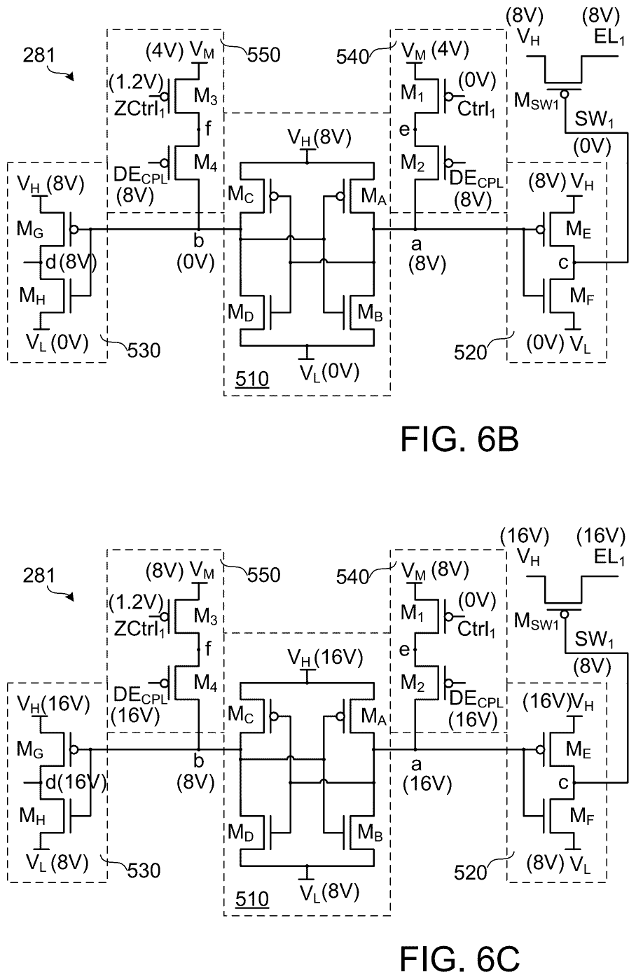

FIGS. 6A, 6B and 6C schematically illustrate the voltages at various nodes of the switch controller 281 of the third embodiment in different phases.

Please refer to FIG. 6A. In the logic phase PH_{LOGIC}, the logic supply voltage V_{DD} is 1.2 V. That is, the high voltage V_{H} is 1.2 V, the medium voltage V_{M} is 1.2 V, and the low voltage V_{L} is 0 V. For example, the control signal Ctrl₁ is activated and is in a logic low level state (0 V), the inverted control signal ZCtrl₁ is in a logic high level state (1.2 V), and the decoupling signal DE_{CPL} is 0 V. The decoupling signal DE_{CPL} of about 0 V can be regarded as the decoupling signal DE_{CPL} not activated, that is, the decoupling signal DE_{CPL} is not activated in the logic phase PH_{LOGIC}. Meanwhile, in the control stage 540, the transistor M₁ is turned on, the transistor M₂ is turned on, and the voltages at the nodes e and a are pulled up to 1.2 V. In the control stage 550, the transistor M₃ is turned off. Consequently, the voltage at the node b is pulled down to 0 V by the latch 510, and the latch 510 stores the control signal Ctrl₁ at the node b.

As mentioned above, the voltage at the node b is 0 V. Consequently, in the driving stage 530, the transistor M_{G} is turned on, the transistor M_{H} is turned off, and the voltage at the node d is 1.2 V. The voltage at the node a is 1.2V. Consequently, in the driving stage 520, the transistor M_{F} is turned on, the transistor M_{E} is turned off, and the voltage at the node c is 0 V. That is, the switching signal SW₁ outputted from the driving stage 520 is 0 V. Since the switching signal SW₁ is 0 V, the switching transistor M_{SW1} is turned on, and the high voltage V_{H} (1.2 V) is transmitted to the erase line EL₁. That is, in the logic phase PH_{LOGIC}, the voltage of the erase line EL₁ is 1.2 V and has not risen to the erase voltage V_{EE}. Consequently, the sector erase cannot be performed.

Please refer to FIG. 6B. In the transition phase PH_{TRN}, the high voltage V_{H} is 8 V, the medium voltage V_{M} is 4 V, and the low voltage V_{L} is 0 V. The control signal Ctrl is in the logic low level state (0 V). The inverted control signal ZCtrl₁ is in the logic high level state (1.2 V). The decoupling signal DE_{CPL} is 8 V, that is, the decoupling signal DE_{CPL} is activated in the transition phase PH_{TRN}. Since the decoupling signal DE_{CPL} is 8V, the decoupling signal DE_{CPL} is activated in the control stage 540. Consequently, the transistor M₂ is turned off, and the control stage 540 is decoupled from the node a. Similarly, the decoupling signal DE_{CPL} is activated in the control stage 550. Consequently, the transistor M₄ is turned off, and the control stage 550 is decoupled from the node b.

As mentioned above, the high voltage V_{H} rises to 8 V. The voltage at the node a is pulled up to 8 V by the latch 510. The voltage at the node b is maintained at 0 V. Consequently, in the driving stage 530, the transistor M_{G} is turned on, the transistor M_{H} is turned off, and the voltage at the node d is 8 V. As mentioned above, the voltage at the node a is 8 V. Consequently, in the driving stage 520, the transistor M_{F} is turned on, the transistor M_{E} is turned off, and the voltage at the node c is 0 V. That is, the switching signal SW₁ outputted from the driving stage 520 is 0 V. Since the switching signal SW₁ is 0 V, the switching transistor M_{SW1} is turned on, and the high voltage V_{H} (8 V) is transmitted to the erase line EL₁. That is, in the transition phase PH_{TRN}, the voltage of the erase line EL₁ is 8V and has not risen to the erase voltage V_{EE}. Consequently, the sector erase cannot be performed.

Please refer to FIG. 6C. In the erase phase PH_{ERS}, the high voltage V_{H} is 16 V (i.e., V_{EE}), the medium voltage V_{M} is 8 V, and the low voltage V_{L} is 8 V. The control signal Ctrl₁ is in the logic low level state (0 V). The inverted control signal ZCtrl₁ is in the logic high level state (1.2 V). The decoupling signal DE_{CPL} is 16 V, that is, the decoupling signal DE_{CPL} is activated in the erase phase PH_{ERS}. Since the decoupling signal DE_{CPL} is 16 V, the decoupling signal DE_{CPL} is activated in the control stage 540. Consequently, the transistor M₂ is turned off, and the control stage 540 is decoupled from the node a. Similarly, the decoupling signal DE_{CPL} is activated in the control stage 550. Consequently, the transistor M₄ is turned off, and the control stage 550 is decoupled from the node b.

As mentioned above, the high voltage V_{H} rises to 16 V, and the low voltage V_{L} rises to 8 V. The voltage at the node a is further pulled up to 16 V by the latch 510. The voltage at the node b is pulled up to 8 V by the latch 510. Consequently, in the driving stage 530, the transistor M_{G} is turned on, the transistor M_{H} is turned off, and the voltage at the node d is 16 V. As mentioned above, the voltage at the node a is 16 V. Consequently, in the driving stage 520, the transistor M_{F} is turned on and the transistor M_{E} is turned off, and the voltage at the node c is 8 V. That is, the switching signal SW₁ outputted from the driving stage 520 is 8 V. Since the switching signal SW₁ is 8 V, the switching transistor M_{SW1} is turned on, and the high voltage V_{H} (16 V) is transmitted to the erase line EL₁. Meanwhile, the voltage of the erase line EL₁ is 16 V and equal to the erase voltage V_{EE}. That is, when the power supplying circuit 260 enters the erase phase PH_{ERS}, the erase voltage V_{EE} can be transmitted to the first sector SE₁ through the erase line EL₁. Consequently, the memory cells in the first sector SE₁ are erased into the erased state.

In case that the control signal Ctrl₁ is not activated, the control signal Ctrl₁ is in the logic high level state (1.2 V), the inverted control signal ZCtrl₁ is in the logic low level state (0 V). The switching signal SW₁ generated in each of the logic phase PH_{LOGIC}, the transition phase PH_{TRN} and the erase phase PH_{ERS} can be referred to voltage of the node d in FIGS. 6A˜6C. That is, in the logic phase PH_{LOGIC}, the switching signal SW₁ is equal to the high voltage V_{H} (1.2 V), the switching transistor M_{SW1} is turned off, and the high voltage V_{H} (1.2 V) is not transmitted to the erase line EL₁. In the transition phase PH_{TRN}, the switching signal SW₁ is equal to the high voltage V_{H} (8 V), the switching transistor M_{SW1} is turned off, and the high voltage V_{H} (8 V) is not transmitted to the erase line EL₁. In the erase phase PH_{ERS}, the switching signal SW₁ is equal to the high voltage V_{H} (16 V), the switching transistor M_{SW1} is turned off, and the high voltage V_{H} (16 V) is not transmitted to the erase line EL₁. Since the high voltage V_{H} (16 V, i.e., the erase voltage V_{EE}) is not transmitted to the erase line EL₁, the memory cells in the first sector SE₁ will not be erased into the erased state.

According to the operations of FIGS. 6A, 6B and 6C, the maximum voltage stress that all switching transistors in the switch controller 281 can withstand is, for example, about 8.5 V. The voltage stress withstood by each transistor in the switch controller 281 is lower than 8.5 V, owing to the high voltage V_{H}, the medium voltage V_{M}, the low voltage V_{L} and the decoupling signal DE_{CPL} that are increased in a multi-step manner during the different phases. Therefore, the switch controller 281 may not require additional transistors to share the voltage difference between the high voltage V_{H} and the low voltage V_{L} or the voltage difference between the medium voltage V_{M} and the voltage at the node a (or at the node b). Consequently, the switch controller 281 has low area penalty. Similarly, the voltage stress withstood by the switching transistor M_{SW1} is lower than the maximum voltage stress (e.g., 8.5 V). In other words, when the sector erase is performed, the switch controllers 281˜28X and the switching transistors M_{SW1}˜M_{SWX} in the power supplying circuit 260 can be operated normally within the SOA.

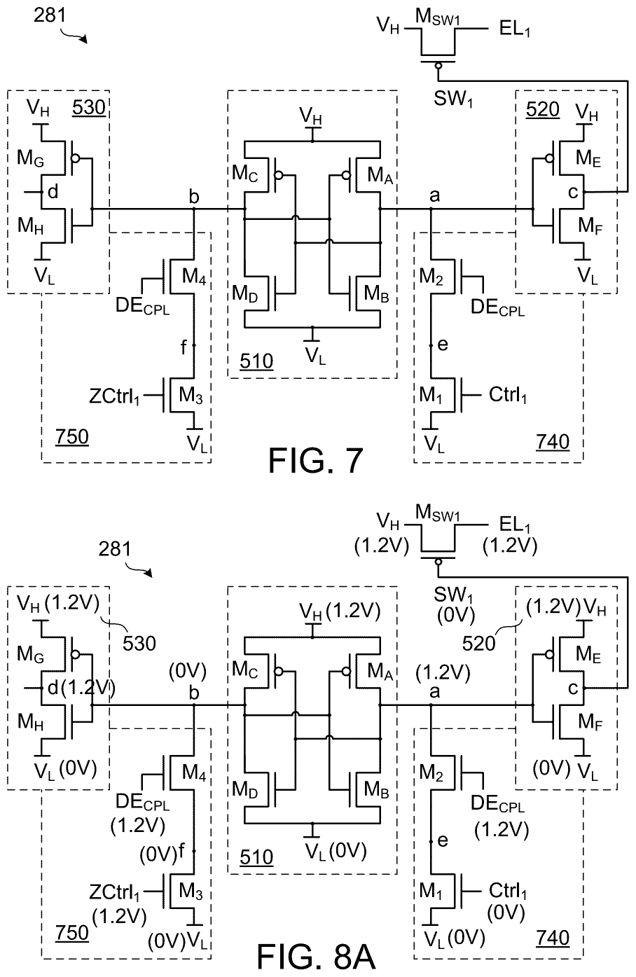

FIG. 7 is a schematic circuit diagram illustrating a switch controller 281 according to a fourth embodiment of the present invention. In comparison with the third embodiment, the structures of the control stages 740 and 750 in the fourth embodiment are distinguished. The structures of the latch 510 and the driving stages 520 and 530 are similar and are not redundantly described herein. For brevity, only the structures of the control stages 740 and 750 will be described as follows.

The control stage 740 comprises two transistors M₁ and M₂. The gate terminal of the transistor M₁ receives the control signal Ctrl₁. The source terminal of the transistor M₁ receives the low voltage V_{L}. The drain terminal of the transistor M₁ is connected with the node e. The gate terminal of transistor M₂ receives the decoupling signal DE_{CPL}. The source terminal of the transistor M₂ is connected with the node e. The drain terminal of the transistor M₂ is connected with the node a.

The control stage 750 comprises two transistors M₃ and M₄. The gate terminal of the transistor M₃ receives the inverted control signal ZCtrl₁. The source terminal of the transistor M₃ receives the low voltage V_{L}. The drain terminal of the transistor M₃ is connected with the node f. The gate terminal of transistor M₄ receives the decoupling signal DE_{CPL}. The source terminal of the transistor M₄ is connected with the node f. The drain terminal of the transistor M₄ is connected with the node b.

In this embodiment, the voltage source 262 needs not to output the medium voltage V_{M} to the switch controllers 281˜28x. In some embodiment, the medium voltage V_{M} may be served as the decoupling signal DE_{CPL}.

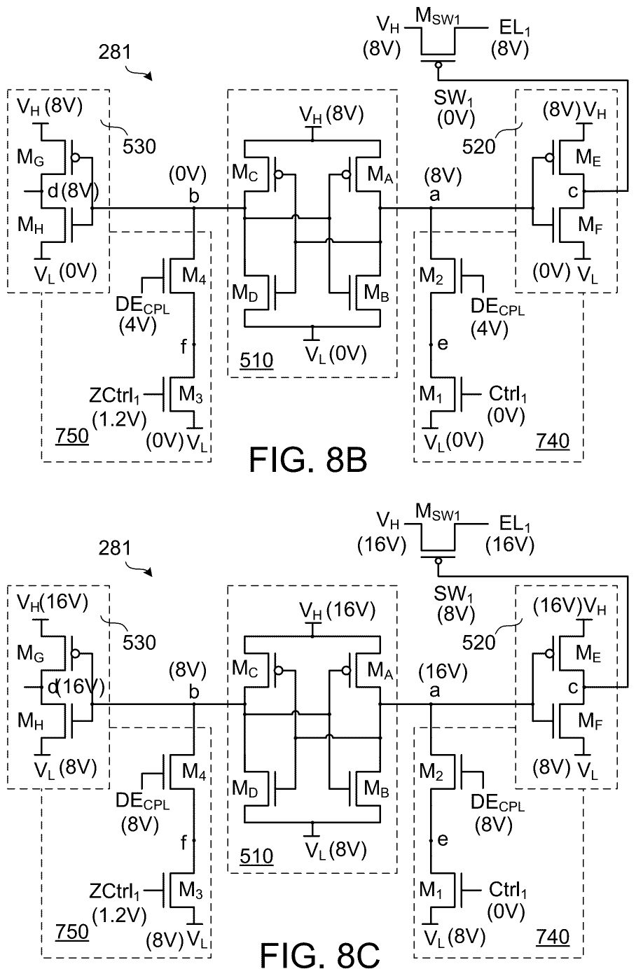

FIGS. 8A, 8B and 8C schematically illustrate the voltages at various nodes of the switch controller 281 of the fourth embodiment in different phases.

Please refer to FIG. 8A. In the logic phase PH_{LOGIC}, the logic supply voltage V_{DD} is 1.2 V. That is, the high voltage V_{H} is 1.2 V and the low voltage V_{L} is 0 V. For example, the control signal Ctrl₁ is activated and is in a logic low level state (0 V), the inverted control signal ZCtrl₁ is in a logic high level state (1.2 V), and the decoupling signal DE_{CPL} is 1.2 V. Meanwhile, in the control stage 750, the transistor M₃ is turned on, the transistor M₄ is turned on, and the voltages at the nodes f and b are pulled down to 0 V. Consequently, the latch 510 stores the control signal Ctrl₁, and the voltage at the node a is pulled up to 1.2 V by the latch 510. Moreover, in the control stage 740, the transistor M₁ is turned off.

As mentioned above, the voltage at the node b is 0 V. Consequently, in the driving stage 530, the transistor M_{G} is turned on, the transistor M_{H} is turned off, and the voltage at the node d is 1.2 V. The voltage at the node a is 1.2 V. Consequently, in the driving stage 520, the transistor M_{F} is turned on, the transistor M_{E} is turned off, and the voltage at the node c is 0 V. That is, the switching signal SW₁ outputted from the driving stage 520 is 0 V. Since the switching signal SW₁ is 0 V, the switching transistor M_{SW1} is turned on, and the high voltage V_{H} (1.2 V) is transmitted to the erase line EL₁. That is, in the logic phase PH_{LOGIC}, the voltage of the erase line EL₁ is 1.2 V and has not risen to the erase voltage V_{EE}. Consequently, the sector erase cannot be performed.

Please refer to FIG. 8B. In the transition phase PH_{TRN}, the high voltage V_{H} is 8V and the low voltage V_{L} is 0 V. The control signal Ctrl₁ is in the logic low level state (0 V). The inverted control signal ZCtrl is in the logic high level state (1.2 V). The decoupling signal DE_{CPL} is 4V. Since the decoupling signal DE_{CPL} is 4V, the transistor M₂ and M₄ are in the conducting state. That means the transistor M₂ and M₄ are turned on. Furthermore, the transistor M₃ in the control stage 750 is turned on by the inverted control signal ZCtrl₁ (1.2 V), and the transistor M₁ in the control stage 740 is turned off by the control signal Ctrl₁ (0 V). Consequently, the voltage at the node b is maintained at 0 V.

As mentioned above, the high voltage V_{H} rises to 8 V. The voltage at the node a is pulled up to 8 V by the latch 510. The voltage at the node b is maintained at 0 V. Consequently, in the driving stage 530, the transistor M_{G} is turned on, the transistor M_{H} is turned off, and the voltage at the node d is 8 V. As mentioned above, the voltage at the node a is 8 V. Consequently, in the driving stage 520, the transistor M_{F} is turned on, the transistor M_{E} is turned off, and the voltage at the node c is 0 V. That is, the switching signal SW₁ outputted from the driving stage 520 is 0 V. Since the switching signal SW₁ is 0 V, the switching transistor M_{SW1} is turned on, and the high voltage V_{H} (8 V) is transmitted to the erase line EL₁. That is, in the transition phase PH_{TRN}, the voltage of the erase line EL₁ is 8 V and has not risen to the erase voltage V_{EE}. Consequently, the sector erase cannot be performed.

Please refer to FIG. 8C. In the erase phase PH_{ERS}, the high voltage V_{H} is 16 V (i.e., V_{EE}), and the low voltage V_{L} is 8 V. The control signal Ctrl₁ is in the logic low level state (0 V). The inverted control signal ZCtrl₁ is in the logic high level state (1.2 V). The decoupling signal DE_{CPL} is 8 V. Since the low voltage V_{L} rises from 0 V to 8 V, the transistor M₁ and transistor M₃ are turned off. In addition, the voltage at the node e and the voltage at the node f rise, causing the transistor M₄ and the transistor M₂ to turn off. Consequently, the control stage 740 is decoupled from the node a. Similarly, control stage 750 is decoupled from the node b.

As mentioned above, the high voltage V_{H} rises to 16 V, and the low voltage V_{L} rises to 8 V. The voltage at the node a is further pulled up to 16 V by the latch 510. The voltage at the node b is pulled up to 8 V by the latch 510. Consequently, in the driving stage 530, the transistor M_{G} is turned on, the transistor M_{H} is turned off, and the voltage at the node d is 16 V. As mentioned above, the voltage at the node a is 16 V. Consequently, in the driving stage 520, the transistor M_{F} is turned on, the transistor M_{E} is turned off, and the voltage at the node c is 8 V. That is, the switching signal SW₁ outputted from the driving stage 520 is 8 V. Since the switching signal SW₁ is 8 V, the switching transistor M_{SW1} is turned on, and the high voltage V_{H} (16 V) is transmitted to the erase line EL₁. Meanwhile, the voltage of the erase line EL₁ is 16 V and equal to the erase voltage V_{EE}. That is, when the power supplying circuit 260 enters the erase phase PH_{ERS}, the erase voltage V_{EE} can be transmitted to the first sector SE₁ through the erase line EL₁. Consequently, the memory cells in the first sector SE₁ are erased into the erased state.

In case that the control signal Ctrl₁ is not activated, the control signal Ctrl₁ is in the logic high level state (1.2 V), the inverted control signal ZCtrl₁ is in the logic low level state (0 V). The switching signal SW₁ generated in each of the logic phase PH_{LOGIC}, the transition phase PH_{TRN} and the erase phase PH_{ERS} can be referred to voltage of the node d in FIGS. 8A˜8C. That is, in the logic phase PH_{LOGIC}, the switching signal SW₁ is equal to the high voltage V_{H} (1.2 V), the switching transistor M_{SW1} is turned off, and the high voltage V_{H} (1.2 V) is not transmitted to the erase line EL₁. In the transition phase PH_{TRN}, the switching signal SW₁ is equal to the high voltage V_{H} (8 V), the switching transistor M_{SW1} is turned off, and the high voltage V_{H} (8 V) is not transmitted to the erase line EL₁. In the erase phase PH_{ERS}, the switching signal SW₁ is equal to the high voltage V_{H} (16 V), and the switching transistor M_{SW1} is turned off. Since the high voltage V_{H} (16 V, i.e., the erase voltage V_{EE}) is not transmitted to the erase line EL₁, the memory cells in the first sector SE₁ will not be erased into the erased state.

According to the operations of FIGS. 8A, 8B and 8C, the maximum voltage stress that all switching transistors in the switch controller 281 can withstand is, for example, about 8.5V. The voltage stress withstood by each transistor in the switch controller 281 is lower than 8.5 V, owing to the high voltage V_{H}, the decoupling signal DE_{CPL} and the low voltage V_{L} that are increased in the multi-step manner during the different phases. Consequently, as aforementioned, the switch controller 281 of FIG. 7 has low area penalty. Similarly, the voltage stress withstood by the switching transistor M_{SW1} is lower than the maximum voltage stress (e.g., 8.5 V). In other words, when the sector erase is performed, the switch controllers 281˜28X and the switching transistors M_{SW1}˜M_{SWX} in the power supplying circuit 260 can be operated normally within the SOA.

In the switch controller 281 of the fourth embodiment, the node e of the control stage 740 and the node f of the control stage 750 are possibly in the floating state in the erase phase PH_{ERS}. Consequently, the control stages 740 and 750 of the fourth embodiment can be further modified.

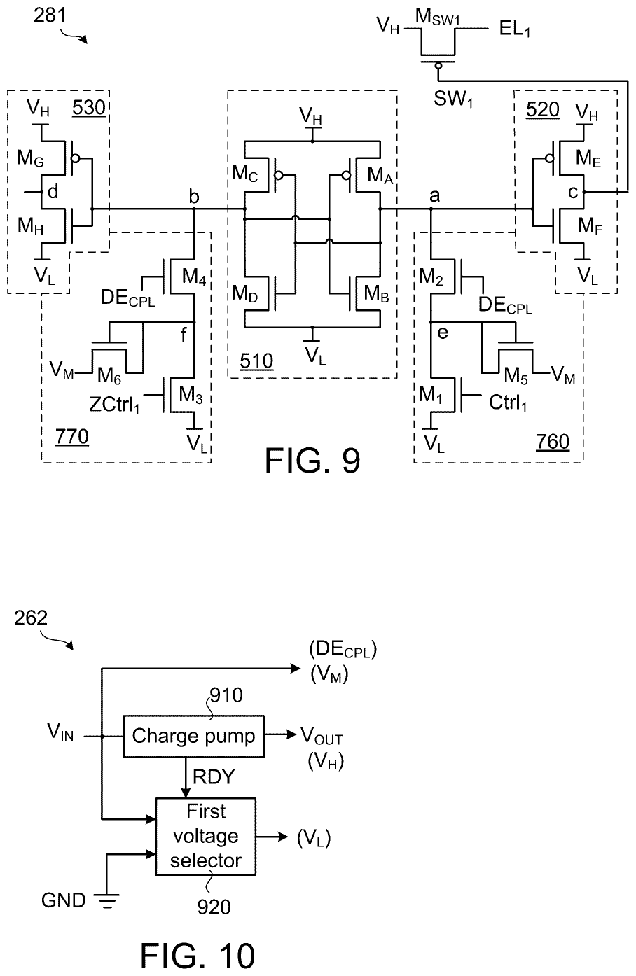

FIG. 9 is a schematic circuit diagram illustrating a switch controller 281 according to a fifth embodiment of the present invention. In comparison with the fourth embodiment, the structures of the control stages 760 and 770 in the fifth embodiment are distinguished. The control stage 760 further comprises a diode-connected transistor M₅. The control stage 770 further comprises a diode-connected transistor M₆. The operations of the switch controller 281 in the fifth embodiment are similar to the operations of the switch controller 281 in the fourth embodiment, and therefore are not redundantly described herein. For brevity, only the structures of the control stages 760 and 770 will be described as follows.

In the control stage 760, the drain terminal of the transistor M₅ receives the medium voltage V_{M}, the gate terminal of the transistor M₅ is connected with the node e, and the source terminal of the transistor M₅ is connected with the node e. In the control stage 770, the drain terminal of the transistor M₆ receives the medium voltage V_{M}, the gate terminal of the transistor M₆ is connected with the node f, and the source terminal of the transistor M₆ is connected with the node f. When the transistor M₁ of the control stage 760 is turned off in the erase phase PH_{ERS}, the node e is floating and may be coupled to a high voltage. When the node e is coupled to the high voltage, the transistor M₅ will be turned on and the voltage at the node e will be equal to the medium voltage V_{M} minus the threshold voltage V_{TH5} of the transistor M₅, i.e., (V_{M}−V_{TH5}). For example, in case that the medium voltage V_{M} is 1.2 V and the threshold voltage V_{TH5} of the transistor M₅ is 0.5 V, the voltage at the node e is 0.7 V. Similarly, when the transistor M₃ of the control stage 770 is turned off in the erase phase PH_{ERS}, the voltage at the node f is equal to the medium voltage V_{M} minus the threshold voltage V_{TH6} of the transistor M₆ (i.e., (V_{M}-VTH). For example, in case that the medium voltage V_{M} is 1.2 V and the threshold voltage V_{TH6} of transistor M₆ is 0.5 V, the voltage at the node f is 0.7 V.

Similarly, in the switch controller 281 of the third embodiment shown in FIG. 5, the control stage 540 may be additionally equipped with a first diode-connected transistor, and the control stage 550 may be additionally equipped with a second diode-connected transistor. The first diode-connected transistor is connected with the node e to discharge the node e when the node e is coupled to the high voltage. The second diode-connected transistor is connected with the node f to discharge the node f when the node f is coupled to the high voltage.

The voltage source 262 in the power supplying circuit 260 may be implemented with a charge pump and a voltage selector. The concept of this voltage source 262 can be applied to the switch controller of the fourth embodiment and the switch controller of the fifth embodiment.

FIG. 10 is a schematic circuit diagram illustrating the voltage source 262 in the power supplying circuit 260. As shown in FIG. 10, the voltage source 262 comprises a charge pump 910 and a first voltage selector 920. The input voltage VIN of the charge pump 910 can be used as the decoupling signal DE_{CPL} in the fourth embodiment, or as both the decoupling signal DE_{CPL} and the medium voltage V_{M} to be outputted from the voltage source 262 in the fifth embodiment. The output voltage V_{OUT} of the charge pump 910 can be used as the high voltage V_{H} to be outputted from the voltage source 262. In addition, the medium voltage V_{M} is also served as the decoupling signal DE_{CPL}.

For example, before voltage boost function of the charge pump 910 is enabled, the input voltage VIN of the charge pump 910 is equal to the output voltage V_{OUT}. When the voltage boost function of the charge pump 910 is enabled and operated normally, the input voltage VIN is boosted two times to be the output voltage V_{OUT} by the charge pump 910. Moreover, when the output voltage V_{OUT} from the charge pump 910 reaches the highest voltage value, the charge pump 910 activates a ready signal RDY to indicate that the output voltage V_{OUT} from the charge pump 910 reaches the highest voltage value. In this embodiment, the highest voltage value of the output voltage V_{OUT} from the charge pump 910 is the erase voltage V_{EE}, i.e., 16 V.

The two input terminals of the first voltage selector 920 receive the input voltage VIN and the ground voltage (0 V), respectively. The select terminal of the first voltage selector 920 receives the ready signal RDY. In case that the ready signal RDY is not activated, the first voltage selector 920 selects the ground voltage (0 V) as the low voltage V_{L}. In case that the ready signal RDY is activated, the first voltage selector 920 selects the input voltage VIN as the low voltage V_{L}.

When the non-volatile memory 100 performs a sector erase, the power supplying circuit 260 will sequentially enter a logic phase PH_{LOGIC}, a transition phase PH_{TRN} and an erase phase PH_{ERS}. In the logic phase PH_{LOGIC}, the input voltage VIN received by the voltage source 262 is the logic supply voltage V_{DD} (e.g., 1.2 V). Since the charge pump 910 is not enabled, the ready signal RDY is not activated, and the first voltage selector 920 outputs the ground voltage (0 V). Consequently, the high voltage V_{H} outputted from the voltage source 262 is equal to the logic supply voltage V_{DD}, the decoupling signal DE_{CPL} and/or the medium voltage V_{M} is equal to the logic supply voltage V_{DD}, and the low voltage V_{L} is equal to the ground voltage (0 V).

In the transition phase PH_{TRN}, the input voltage VIN received by the voltage source 262 is 4 V (i.e., V_{EE}/4). Since the charge pump 910 is enabled, the output voltage V_{OUT} from the charge pump 910 is 8 V (i.e., V_{EE}/2). In addition, the ready signal RDY is not activated, and the first voltage selector 920 outputs the ground voltage (0 V). Consequently, the high voltage V_{H} outputted from the voltage source 262 is 8 V (i.e., V_{EE}/2), the decoupling signal DE_{CPL} and/or the medium voltage V_{M} is 4 V (i.e., V_{EE}/4), and the low voltage V_{L} is equal to the ground voltage (0 V).

In the erase phase PH_{ERS}, the input voltage VIN received by the voltage source 262 is 8 V (i.e., V_{EE}/2). Since the charge pump 910 is enabled, the output voltage V_{OUT} from the charge pump 910 is 16 V (i.e., V_{EE}), the ready signal RDY is activated, and the voltage outputted from the first voltage selector 920 is 8 V. Consequently, the high voltage V_{H} outputted from the voltage source 262 is 16 V (i.e., V_{EE}), the decoupling signal DE_{CPL} and/or the medium voltage V_{M} is 8 V (i.e., V_{EE}/2), and the low voltage V_{L} is 8 V (i.e., V_{EE}/2).

Accordingly, the medium voltage V_{M} outputted from the voltage source 262 may be used as the decoupling signal DE_{CPL} and applied to the switch controller of the fourth embodiment and the switch controller of the fifth embodiment. In another embodiment, the voltage source 262 is modified to be applied to the switch controller of the third embodiment, which has the medium voltage V_{M} and the decoupling signal DE_{CPL} of different values.

For example, the voltage source 262 is further equipped with a second voltage selector (not shown). The second voltage selector receives the ground voltage (0V) and the output voltage V_{OUT}. In the logic phase PH_{LOGIC}, the ground voltage (0V) outputted from the second voltage selector is served as the decoupling signal DE_{CPL}. In the transition phase PH_{TRN}, the voltage of 8V is outputted from the second voltage selector and served as the decoupling signal DE_{CPL}. In the erase phase PH_{ERS}, the voltage of 16V is outputted from the second voltage selector and served as the decoupling signal DE_{CPL}.

It is noted that the magnitudes of the high voltage V_{H}, the medium voltage V_{M}, the low voltage V_{L} and the decoupling signal DE_{CPL} are not restricted. That is, the voltage source may be designed according to the practical requirements. The magnitudes of the high voltage V_{H}, the medium voltage V_{M} and the low voltage V_{L} may be determined according to the erase voltage V_{EE} and the maximum voltage stress that the switching transistors M_{SW1}˜M_{SWX} and the switch controllers 281˜28X can withstand.

Take the switch controller 281 of the fifth embodiment for example. It is assumed that the erase voltage V_{EE} is 13 V and the maximum voltage stress capable of being withstood by the switching transistors is 7 V. In the logic phase PH_{LOGIC}, the high voltage V_{H} is equal to the logic supply voltage V_{DD} (e.g., 1.2 V), the low voltage V_{L} is equal to 0 V, and the medium voltage V_{M} and the decoupling signal DE_{CPL} are in the range of the high voltage V_{H} and the low voltage V_{L}. The magnitude of the medium voltage V_{M} is not restricted as long as the transistor M₅ and the transistor M₆ can be turned on.) For example, the medium voltage V_{M} is 1 V.

In the transition phase PH_{TRN}, the high voltage V_{H} can be set to be slightly less than the maximum stress that the transistor can withstand. The medium voltage V_{M} and the decoupling signal DE_{CPL} are lower than the high voltage V_{H}. The medium voltage V_{M} and the decoupling signal DE_{CPL} are higher than the low voltage V_{L}. For example, the high voltage V_{H} is set to 7 V, the medium voltage V_{M} and the decoupling signal DE_{CPL} are set to 4 V, and the low voltage V_{L} is set to 0 V.

In the erase phase PH_{ERS}, the high voltage V_{H} is set to the erase voltage V_{EE}. The medium voltage V_{M} and the decoupling signal DE_{CPL} are lower than the high voltage V_{H}. The medium voltage V_{M} and the decoupling signal DE_{CPL} are equal to the low voltage V_{L}. For example, the high voltage V_{H} is set to 13 V (i.e., V_{EE}), the medium voltage V_{M} and the decoupling signal DE_{CPL} are set to 8 V, and the low voltage V_{L} is set to 8 V.

From the above descriptions, the present invention provides a power supplying circuit and an associated switch controller for a non-volatile memory. When the sector erase is performed, the voltage stress withstood by the switching transistors in the power supplying circuit is lower than the maximum voltage stress. In addition, the voltage stress withstood by all transistors in the switch controller is lower than the maximum voltage stress. In other words, when the sector erase is performed, all switch controllers and all switching transistors in the power supplying circuit 260 can be operated normally within the SOA.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supplying circuit for a non-volatile memory, the power supplying circuit comprising a voltage source and a switching circuit, the voltage source outputting a high voltage, a low voltage and a decoupling signal, the switching circuit comprising a power switch and a switch controller, a first terminal of the power switch receiving the high voltage, a second terminal of the power switch being coupled to an erase line of the non-volatile memory, the switch controller comprising:
a latch, wherein a first power terminal of the latch receives the high voltage, a second power terminal of the latch receives the low voltage, a first control terminal of the latch is connected with a first node, and a second control terminal of the latch is connected with a second node;
a first driving stage, wherein a first power terminal of the first driving stage receives the high voltage, a second power terminal of the first driving stage receives the low voltage, an input terminal of the first driving stage is connected with the first node, an output terminal of the first driving stage generates a switching signal to a control terminal of the power switch, and on/off states of the power switch are controlled according to the switching signal;
a first control stage connected with the first node, wherein the first control stage receives a control signal and the decoupling signal; and
a second control stage connected with the second node, wherein the second control stage receives an inverted control signal and the decoupling signal,
wherein in a logic phase of a sector erase, the high voltage is equal to a logic supply voltage, the low voltage is equal to a ground voltage, and the control signal is stored in the latch;
wherein in a transition phase of the sector erase, the high voltage rises from the logic supply voltage to a first voltage, the low voltage is equal to the ground voltage;
wherein in an erase phase of the sector erase, the high voltage rises from the first voltage to an erase voltage, the low voltage rises from the ground voltage to a second voltage, the erase voltage is higher than the second voltage, and the first driving stage generates the switching signal according to the high voltage and the low voltage;
wherein the decoupling signal is in a range of the high voltage and the low voltage during the logic phase, the transition phase and the erase phase.

2. The power supplying circuit as claimed in claim 1, wherein in the transition phase of the sector erase, the decoupling signal is activated, the first control stage is decoupled from the first node, and the second control stage is decoupled from the second node.

3. The power supplying circuit as claimed in claim 1, wherein the latch comprises:
a first inverter, wherein a first power terminal of the first inverter receives the high voltage, a second power terminal of the first inverter receives the low voltage, an input terminal of the first inverter is connected with the second node, and an output terminal of the first inverter is connected with the first node; and
a second inverter, wherein a first power terminal of the second inverter receives the high voltage, a second power terminal of the second inverter receives the low voltage, an input terminal of the second inverter is connected with the first node, and an output terminal of the second inverter is connected with the second node.

4. The power supplying circuit as claimed in claim 3, wherein the first driving stage comprises a third inverter, wherein a first power terminal of the third inverter receives the high voltage, a second power terminal of the third inverter receives the low voltage, an input terminal of the third inverter is connected with the first node, and an output terminal of the third inverter generates the switching signal.

5. The power supplying circuit as claimed in claim 4, wherein the power supplying circuit further comprises a second driving stage, wherein a first power terminal of the second driving stage receives the high voltage, a second power terminal of the second driving stage receives the low voltage, and an input terminal of the second driving stage is connected with the second node.

6. The power supplying circuit as claimed in claim 1, wherein the voltage source further outputs a medium voltage, the medium voltage is in the range of the high voltage and the low voltage during the logic phase, the transition phase and the erase phase, the first control stage comprises:
a first transistor, wherein a source terminal of the first transistor receives the medium voltage, a gate terminal of the first transistor receives the control signal, and a drain terminal of the first transistor is connected with a third node; and
a second transistor, wherein a source terminal of the second transistor is connected with the third node, a gate terminal of the second transistor receives the decoupling signal, and a drain terminal of the second transistor is connected with the first node.

7. The power supplying circuit as claimed in claim 6, wherein the second control stage comprises:
a third transistor, wherein a source terminal of the third transistor receives the medium voltage, a gate terminal of the third transistor receives the inverted control signal, and a drain terminal of the third transistor is connected with a fourth node; and
a second transistor, wherein a source terminal of the fourth transistor is connected to the fourth node, a gate terminal of the fourth transistor receives the decoupling signal, and a drain terminal of the fourth transistor is connected with the second node.

8. The power supplying circuit as claimed in claim 7, wherein in the logic phase, the high voltage outputted from the voltage source is equal to the logic supply voltage, the medium voltage outputted from the voltage source is equal to the logic supply voltage, the low voltage outputted from the voltage source is equal to the ground voltage, and the decoupling signal is equal to the ground voltage.

9. The power supplying circuit as claimed in claim 8, wherein in the transition phase, the high voltage outputted from the voltage source is equal to a half of the erase voltage, the medium voltage outputted from the voltage source is equal to one-quarter of the erase voltage, the low voltage outputted from the voltage source is equal to the ground voltage, and the decoupling signal is equal to a half of the erase voltage.

10. The power supplying circuit as claimed in claim 9, wherein in the erase phase, the high voltage outputted from the voltage source is equal to the erase voltage, the medium voltage outputted from the voltage source is equal to a half of the erase voltage, the low voltage outputted from the voltage source is equal to a half of the erase voltage, and the decoupling signal is equal to the erase voltage.

11. The power supplying circuit as claimed in claim 1, wherein the first control stage comprises:
a first transistor, wherein a source terminal of the first transistor receives the low voltage, a gate terminal of the first transistor receives the control signal, and a drain terminal of the first transistor is connected with a third node; and
a second transistor, wherein a source terminal of the second transistor is connected with the third node, a gate terminal of the second transistor in receives the decoupling signal, and a drain terminal of the second transistor is connected with the first node.

12. The power supplying circuit as claimed in claim 11, wherein the second control stage comprises:
a third transistor, wherein a source terminal of the third transistor receives the low voltage, a gate terminal of the third transistor receives the inverted control signal, and a drain terminal of the third transistor is connected with a fourth node; and
a fourth transistor, wherein a source terminal of the fourth transistor is connected to the fourth node, a gate terminal of the fourth transistor receives the decoupling signal, and a drain terminal of the fourth transistor is connected with the second node.

13. The power supplying circuit as claimed in claim 12, wherein the voltage source further outputs a medium voltage, the medium voltage is in the range of the high voltage and the low voltage during the logic phase, the transition phase and the erase phase, the first control stage further comprises a fifth transistor, the second control stage further comprises a sixth transistor, a drain terminal of the fifth transistor receives the medium voltage, a gate terminal of the fifth transistor is connected with the third node, a source terminal of the fifth transistor is connected with the third node, a drain terminal of the sixth transistor receives the medium voltage, a gate terminal of the sixth transistor is connected with the fourth node, and a source terminal of the sixth transistor is connected with the fourth node.

14. The power supplying circuit as claimed in claim 12, wherein in the logic phase, the high voltage outputted from the voltage source is equal to the logic supply voltage, the medium voltage outputted from the voltage source is equal to the logic supply voltage, and the low voltage outputted from the voltage source is equal to the ground voltage, wherein the decoupling signal is equal to the medium voltage.

15. The power supplying circuit as claimed in claim 14, wherein in the transition phase, the high voltage outputted from the voltage source is equal to a half of the erase voltage, the medium voltage outputted from the voltage source is equal to one-quarter of the erase voltage, and the low voltage outputted from the voltage source is equal to the ground voltage.

16. The power supplying circuit as claimed in claim 15, wherein in the erase phase, the high voltage outputted from the voltage source is equal to the erase voltage, the medium voltage outputted from the voltage source is equal to a half of the erase voltage, and the low voltage outputted from the voltage source is equal to a half of the erase voltage.

17. The power supplying circuit as claimed in claim 1, wherein the latch comprises:
a first transistor, wherein a source terminal of the first transistor receives the high voltage, a gate terminal of the first transistor is connected with the second node, and a drain terminal of the first transistor is connected with the first node;
a second transistor, wherein a source terminal of the second transistor receives the low voltage, a gate terminal of the second transistor is connected with the second node, and a drain terminal of the second transistor is connected with the first node;
a third transistor, wherein a source terminal of the third transistor receives the high voltage, a gate terminal of the third transistor is connected with the first node, and a drain terminal of the third transistor is connected with the second node; and
a fourth transistor, wherein a source terminal of the fourth transistor receives the low voltage, a gate terminal of the fourth transistor is connected with the first node, and a drain terminal of the fourth transistor is connected with the second node.

18. The power supplying circuit as claimed in claim 17, wherein the first driving stage comprises:
a fifth transistor, wherein a source terminal of the fifth transistor receives the high voltage, a gate terminal of the fifth transistor is connected with the first node, and a drain terminal of the fifth transistor is connected with a fifth node;
a sixth transistor, wherein a source terminal of the sixth transistor receives the low voltage, a gate terminal of the sixth transistor is connected with the first node, and a drain terminal of the sixth transistor is connected with the fifth node,
wherein the fifth node is the output terminal of the first driving stage.

19. The power supplying circuit as claimed in claim 17, wherein the power supplying circuit further comprises a second driving stage, and the second driving stage comprises:
a seventh transistor, wherein a source terminal of the seventh transistor receives the high voltage, a gate terminal of the seventh transistor is connected with the second node, and a drain terminal of the seventh transistor is connected with a sixth node; and
an eighth transistor, wherein a source terminal of the eighth transistor receives the low voltage, a gate terminal of the eighth transistor is connected with the second node, and a drain terminal of the eighth transistor is connected with the sixth node.

20. The power supplying circuit as claimed in claim 1, wherein in response to the control signal of a first logic level, the power switch is turned on according to the switching signal to transmit the logic supply voltage, the first voltage and the erase voltage to the erase line respectively in the logic phase, the transition phase and the erase phase.

21. The power supplying circuit as claimed in claim 20, wherein in response to the control signal of a second logic level, the power switch is turned off according to the switching signal in the logic phase, the transition phase and the erase phase.

22. A power supplying circuit for a non-volatile memory, wherein the power supplying circuit comprises a power switch, a switch controller and a voltage source, the voltage source is configured to output a high voltage, a low voltage and a decoupling signal, a first terminal of the power switch is configured to receive the high voltage, a second terminal of the power switch is coupled to an erase line of the non-volatile memory, the switch controller is configured to receive the high voltage, the low voltage and the decoupling signal and the switch controller comprises:
a latch, wherein a first control terminal of the latch is coupled to a first node, and a second control terminal of the latch is coupled to a second node;
a first driving stage coupled to the first node and a control terminal of the power switch, and configured to output the high voltage or the low voltage as a switching signal to the control terminal of the power switch according to a voltage at the first node;
a first control stage coupled to the first node, and configured to control the voltage at the first node according to a control signal and the decoupling signal; and
a second control stage coupled to the second node, and configured to control a voltage at the second node according to an inverted control signal and the decoupling signal,
wherein the high voltage, the low voltage and the decoupling signal are increased in a multi-step manner during a sector erase of the non-volatile memory, wherein the decoupling signal is in a range of the high voltage and the low voltage during the sector erase.
